(19) United States
(12) Patent Application Publication
(10) Pub. No.: US 2007/0278513 A1
(43) Pub. Date: Dec. 6, 2007

(54) Semiconductor light emitting device and method of fabricating the same

(75) Inventor: Hiroshi Chikugawa, Kashihara-shi (JP)

Correspondence Address: MORRISON & FOERSTER LLP, 1650 TYSONS BOULEVARD, SUITE 400, MCLEAN, VA, 22102, US

(73) Assignee: Sharp Kabushiki Kaisha, Osaka-shi (JP)

(21) Appl. No.: 11/806,233

(22) Filed: May 30, 2007

(30) Foreign Application Priority Data
Jun. 1, 2006 (JP) 2006-153833

(51) Int. Cl. H01L 33/00; H01L 21/00

(52) U.S. Cl. 257/100; 438/22; 257/E33.059

(57) ABSTRACT

There is provided a method that allows fabrication, through a simple process, of a good quality semiconductor light emitting device having a semiconductor light emitting element surrounded and thus covered with a fluorescent layer formed of resin uniform in thickness. At least two semiconductor light emitting elements are bonded to a substrate with a predetermined interval. Subsequently a first resin serving as a fluorescent layer is molded across the entire surface of the substrate substantially parallel to the top surface of the semiconductor light emitting element to cover the semiconductor light emitting element. After the first resin is cured, the first resin is at least partially diced.

This nonprovisional application is based on Japanese Patent Application No. 2006-153833 filed with the Japan Patent Office on Jun. 1, 2006, the entire contents of which are hereby incorporated by reference.

### BACKGROUND OF THE INVENTION

1. Field of the Invention

The present invention relates to semiconductor light emitting devices having a light emitting element surrounded by a resin region having a uniform thickness and containing a fluorescent substance mixed therein, and method of fabricating the same.

2. Description of the Background Art

A semiconductor light emitting device employing a light emitting element such as a light emitting diode (LED) and emitting white light of high quality is being studied and developed. One method of generating such white light utilizes fluorescent substances of red color, blue color, green color, yellow color and the like. More specifically, if a portion of light of a semiconductor light emitting element emitting blue light is absorbed by fluorescent substances and converted in wavelength to emit red light and green light, the lights of the two colors generated by the fluorescent substances and the blue light of the semiconductor light emitting element are combined together to emit white light.

A form of such semiconductor light emitting device that utilizes a fluorescent substance is shown in FIG. 9. A semiconductor light emitting element 902 bonded to a lead frame 905 is attached to a package 906 having a reflector 904 formed of a resin of white color having a high reflectance. Semiconductor light emitting element 902 is sealed with a resin 901 containing a fluorescent substance mixed therein.

Semiconductor light emitting element 902 is bonded via a wire 903 and thus electrically connected. Currently, such semiconductor light emitting device emitting white light is utilized as an illumination device for a camera, a back light for a liquid crystal display device, and the like.

Such semiconductor light emitting device as shown in FIG. 9, however, provides white light varying in chromaticity for different angles at which it is seen. This is because such a phenomenon is caused as follows: semiconductor light emitting element 902 emits light in different directions. Accordingly the light travels different paths and accordingly, passes through resin 901 by traveling different distances. The light that passes through a thick portion of resin 901 is absorbed more than that passing through a thin portion of resin 901.

Accordingly a semiconductor light emitting device having a semiconductor light emitting element surrounded by a resin region having a uniform thickness and a fluorescent substance mixed therein. Hereinafter such region will also be referred to as a fluorescent layer. More specifically, whatever path the light emitted from the semiconductor light emitting element may travel, the light passes through the fluorescent layer by traveling substantially the same distance, and the light emitted through the wavelength conversion provided by the fluorescent substance can have a fixed ratio. As a result, at whatever angle the light may been seen, the light can be uniform in chromaticity. Such semiconductor light emitting devices are disclosed for example in the publications indicated hereinafter. Hereinafter each publication will be described with terms used therein.

Japanese Patent Laying-open No. 2002-185048 discloses such a method that a light emitting semiconductor device provided on a substrate is positioned in an opening of a stencil and a compound containing a light emitting material is subsequently deposited at the opening of the stencil to finally form a layer containing the light emitting material and surrounding the light emitting semiconductor device to have a substantially uniform thickness. Furthermore, Japanese Patent Laying-open No. 2003-110153 describes a method employing a stencil, as well as Japanese Patent Laying-open No. 2002-185048, and a method utilizing electrophoresis to deposit a structure of luminescent material on a light emitting element. Furthermore Japanese Patent Laying-open No. 2006-037097 describes such a method that a light emitting material is mixed into an inorganic material serving as a binder to previously produce a sheet of a wavelength conversion material which is in turn formed to be concaved to provide a wavelength conversion element which covers an LED die for attachment.

### SUMMARY OF THE INVENTION

In the method employing a stencil, as described in Japanese Patent Laying-open No. 2002-185048, if the light emitting semiconductor device positioned in the stencil is even slightly offset, all light emitting semiconductor devices will be positioned offset, and the layer containing the light emitting material cannot be uniform in thickness. Furthermore, as the light emitting semiconductor device is small in size, a source material of the layer containing the light emitting material that is placed at the opening of the stencil must strictly be controlled in viscosity and amount before it is cured, and after it is cured, there is a concern of whether the product is successfully released from the stencil. Furthermore, the source material of the layer containing the light emitting material must be introduced into the stencil for each opening, which results in a complicated process and is also time consuming.

Furthermore, the method utilizing electrophoresis as disclosed in Japanese Patent Laying-open No. 2003-110153 requires that the light emitting element or the like be charged, and depositing the structure requires a long period of time. Furthermore, the method that covers an LED die with a previously prepared sheet, as described in Japanese Patent Laying-open No. 2006-037097, provides the sheet for each LED die, which is time consuming for mass production. Furthermore the method requires that a gap between the LED die and the wavelength conversion element be eliminated. This requires that additional resin be introduced to fill the gap.

Thus surrounding and thus covering a semiconductor light emitting element with a fluorescent layer having a uniform thickness is a cumbersome step and time consuming. The present invention contemplates a method that allows fabrication, through a simple process, of a good quality semiconductor light emitting device having a semiconductor light emitting element surrounded and thus covered with a fluorescent layer uniform in thickness.

The present semiconductor light emitting device is fabricated by a process; comprising the steps of bonding at least two semiconductor light emitting elements to one of a substrate and a submount with a predetermined interval; molding a first resin across an entire surface of one of the substrate and the submount substantially parallel to a top surface of the semiconductor light emitting element to cover the semiconductor light emitting element; and after the first resin is cured, dicing and thus penetrating the first resin and the substrate to provide the first resin with a thickness D1 and a thickness D2 on the top surface and a side surface, respectively, of the semiconductor light emitting element such that a ratio of D2/D1 is 0.85 to 1.15.

Furthermore the present semiconductor light emitting device is fabricated by a process; comprising the steps of bonding at least two semiconductor light emitting elements to one of a substrate and a submount with a predetermined interval; molding a first resin across an entire surface of one of the substrate and the submount substantially parallel to a top surface of the semiconductor light emitting element to cover the semiconductor light emitting element; and after the first resin is cured, dicing the first resin at least partially to provide the first resin with a thickness D1 and a thickness D2 on the top surface and a side surface, respectively, of the semiconductor light emitting element such that a ratio of D2/D1 is 0.85 to 1.15.

Furthermore, in the present semiconductor light emitting device, preferably the first resin contains a fluorescent substance mixed therein. Preferably, after the step of dicing, a surface of the first resin covering the semiconductor light emitting element is covered with a second resin. Preferably the first resin covering the semiconductor light emitting element has a thickness of 50 μm to 500 μm.

Furthermore, in the present semiconductor light emitting device, preferably the first resin includes silicone resin as a source material. Preferably the second resin is epoxy resin. Preferably the first resin having been cured has a smaller modulus of elasticity than the second resin having been cured. Preferably the second resin is smaller in moisture absorptivity than the first resin. Preferably the first resin has a larger index of refraction than the second resin.

Furthermore, in the present semiconductor light emitting device, preferably the semiconductor light emitting element has a bottom surface having a p type electrode and an n type electrode. Furthermore, preferably the semiconductor light emitting element is bonded with one of gold and solder to a ceramic or silicon carbide substrate electrically conducting via a through hole.

Furthermore, in the present semiconductor light emitting device, preferably, in the step of bonding, the substrate is an aluminum substrate formed of an aluminum plate, an insulation layer overlying the aluminum plate, and a copper foil overlying the insulation layer and forming a circuit pattern.

Furthermore preferably the above described semiconductor light emitting device is mounted on a package having a refractor such that the semiconductor light emitting device is surrounded by the reflector.

Furthermore the present method of fabricating a semiconductor light emitting device includes the steps of bonding at least two semiconductor light emitting elements to one of a substrate and a submount with a predetermined interval; molding a first resin across an entire surface of one of the substrate and the submount substantially parallel to a top surface of the semiconductor light emitting element to cover the semiconductor light emitting element; and after the first resin is cured, dicing and thus penetrating the first resin and the substrate to provide the first resin with a thickness D1 and a thickness D2 on the top surface and a side surface, respectively, of the semiconductor light emitting element such that a ratio of D2/D1 is 0.85 to 1.15.

Furthermore the present method of fabricating a semiconductor light emitting device includes the steps of bonding at least two semiconductor light emitting elements to one of a substrate and a submount with a predetermined interval; molding a first resin across an entire surface of one of the substrate and the submount substantially parallel to a top surface of the semiconductor light emitting element to cover the semiconductor light emitting element; and after the first resin is cured, dicing the first resin at least partially to provide the first resin with a thickness D1 and a thickness D2 on the top surface and a side surface, respectively, of the semiconductor light emitting element such that a ratio of D2/D1 is 0.85 to 1.15.

Collectively forming a fluorescent layer can facilitate controlling a fluorescent substance-containing resin in amount and viscosity before the resin is cured. This can contribute to increased mass production and improved quality. Furthermore, dicing the first resin containing the fluorescent substance and having been set and a substrate or a submount simultaneously can contribute to a simplified fabrication process.

Furthermore a high quality semiconductor light emitting device that can be used for a back light of a display device employing liquid crystal, a light source module for illumination, and the like can be fabricated through a simple process constantly and its mass productivity can thus be increased.

The ratio of D2/D1 is tolerable when it is 0.85 to 1.15 The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A-1C are simplified cross sections, respectively, of a semiconductor light emitting device for illustrating a process in one embodiment of the present invention.

FIG. 2 is a cross section of a semiconductor light emitting device for illustrating the step of dicing in one embodiment of the present invention.

FIG. 3 is a cross section of a semiconductor light emitting device for illustrating the step of dicing in one embodiment of the present invention.

FIG. 4 is a cross section of a semiconductor light emitting device for illustrating the step of dicing in one embodiment of the present invention.

FIG. 5 is a cross section of a semiconductor light emitting device in one embodiment of the present invention.

FIG. 6 is a cross section of one embodiment of a semiconductor light emitting element employed in the present invention.

FIG. 7 is a cross section of a semiconductor light emitting device for illustrating electrical connection and the step of dicing in one embodiment of the present invention.

FIG. 8 is a cross section of a semiconductor light emitting device in one embodiment of the present invention.

FIG. 9 is a cross section of a semiconductor light emitting device in one embodiment as conventional.

### DESCRIPTION OF THE PREFERRED EMBODIMENTS

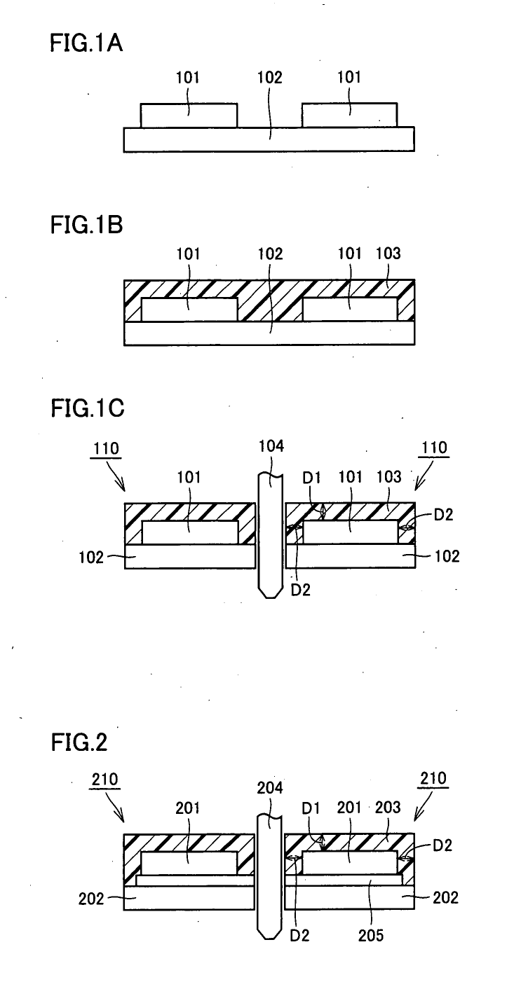

The present fabrication method and device in one embodiment will be described with reference to FIG. 1.

Initially, as shown in FIG. 1A, at least two semiconductor light emitting elements 101 are spaced, as predetermined, on a substrate 102 and thus bonded thereto. In the present invention substrate 102 is a holder holding semiconductor light emitting element 101, and is a concept also including a component serving as an external frame as a package. Furthermore substrate 102 may be a lead frame also serving to externally extract an electrode. Die-bonding as referred to herein means attaching semiconductor light emitting element 101. While such die-bonding is not limited to any particular means, it preferably employs a method using heated gold, solder or the like to connect semiconductor light emitting element 101 to a component to which semiconductor light emitting element 101 is attached. Furthermore, preferably, semiconductor light emitting element 101 emits blue light. The number of semiconductor light emitting elements bonded to the substrate or submount is not limited to any particular number, although how the semiconductor light emitting elements are spaced should be considered. Furthermore, in die-bonding, preferably, electrical connection is provided between substrate 102 and semiconductor light emitting element 101. Such electrical connection and spacing in die-bonding will more specifically be described later.

Then, with reference to FIG. 1B, first resin 103 is applied across the entire surface of substrate 102 to cover semiconductor light emitting element 101 such that first resin 103 is substantially parallel to a top surface of semiconductor light emitting element 101. Note that molding the first resin only on that surface of substrate 102 having a die bonded thereto, suffices. It is not necessary to mold the resin on the surface opposite to that having the die bonded thereto. It should also be noted that the top surface of semiconductor light emitting element 101 is a surface thereof opposite to that bonded to substrate 102. Preferably, semiconductor light emitting element 101 has its all surfaces covered with first resin 103, except for the surface bonded to substrate 102. Note that preferably semiconductor light emitting element 101 is bonded to allow a light emitting layer, which will be described later, to be substantially parallel to substrate 102.

First resin 103 can be molded for example by a representative known method employed in resin-molding, that employs potting equipment.

First resin 103 is implemented by resin containing a fluorescent substance mixed therein. Fluorescent substance refers to a substance that absorbs light emitted from a semiconductor light emitting element and converts the light in wavelength to emit light of a different wavelength, such as red, blue, green, blue green, or the like. Fluorescent substances of such different colors can be mixed to generate white light. Note that the fluorescent substance is dispersed in first resin 103 uniformly. First resin 103 with the fluorescent substance contained therein acts as a fluorescent layer.

Furthermore, preferably, first resin 103 is implemented by silicone resin. Silicone resin is a thermosetting resin formed of a polymer containing bonds with silicon and oxygen with a catalyst such as a curing agent added thereto.

Then, with reference to FIG. 1C, after first resin 103 is cured, first resin 103 and substrate 102 are penetrated or diced to allow first resin 103 to have a thickness D1 on the top surface of semiconductor light emitting element 101 and a thickness D2 on a side surface of semiconductor light emitting element 101 such that a ratio of D2/D1 is 0.85 to 1.15. Dicing as referred to herein is cutting with a dicer 104 to form a groove, and such cutting to form the groove includes both cutting and grinding to form the groove. Furthermore the side surface of semiconductor light emitting element 101 includes any surfaces excluding that the die-bonded surface of semiconductor light emitting element 101 and the top surface of semiconductor light emitting element 101. In the present embodiment, substrate 102 is also penetrated as well as first resin 103 by dicer 104. This step allows each semiconductor light emitting element 110 to be separated.

Furthermore, although it depends on thickness D1 of first resin 103 on the top surface of semiconductor light emitting element 101, first resin 103 on the side surface of semiconductor light emitting element 101 preferably has thickness D2 of 50 μm to 500 μm in order to obtain chromaticity and luminance as desired. Such thickness is also preferable because dicing with dicer 104 to provide first resin 103 smaller in thickness than 50 μm requires high working precision, resulting in a complicated process. Dicing as described above can provide first resin 103 substantially uniform in thickness on the top and side surfaces of semiconductor light emitting element 101. Thus semiconductor light emitting device 110 can be fabricated that allows uniform chromaticity at whatever angle it may be seen.

In FIG. 1A preferably semiconductor light emitting elements 101 that are bonded to substrate 102 are spaced, as predetermined, with a dicing margin also considered, for fabrication, to allow first resin 103 to be substantially uniform in thickness on the top and side surfaces of semiconductor light emitting element 101.

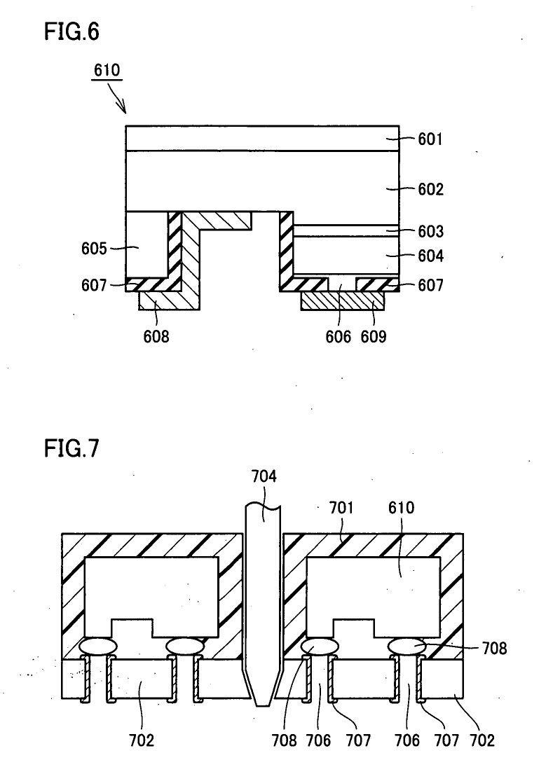

Preferably the present semiconductor light emitting element is such as a semiconductor light emitting element 610, as shown in FIG. 6, having a p electrode 609 and an n electrode 602 provided in one direction to allow flip chip connection. Semiconductor light emitting element 610 is a stack of semiconductor layers having on a device substrate 601 an n type region 602 and a p type region 604, and an active region 603 serving as a light emitting layer. An n contact 605 and a p contact 606 have surfaces, respectively, covered with an insulator 607. The number or semiconductor layers of n type region 602 and p type region 604, and the configuration of active region 603 may be modified as appropriate. Furthermore in the present invention semiconductor light emitting element 610 can be bonded to allow the element's substrate 601 to be a top surface. Furthermore, if p electrode 609 and n electrode 608 are provided in one direction, preferably p electrode 609 and n electrode 608 are substantially equally distant from the element's substrate 601.

In the step of bonding a semiconductor light emitting element to a substrate, as aforementioned, the semiconductor light emitting element is electrically connected. In the present embodiment the semiconductor light emitting element is electrically connected, as will be described hereinafter with reference to FIG. 7. In the present embodiment preferably a substrate 702 is implemented by a ceramic substrate, a silicon carbide substrate or the like having a through hole 706, since such substrate 702 acts to efficiently diffuse heat generated by semiconductor light emitting element 601. Through hole 706 is a bore formed through substrate 702 vertically and plated with conductor to form a terminal 707. Through hole 706 allows substrate 702 to have its top and bottom surfaces in electrical conduction.

Accordingly, by electrically connecting through hole 706 and semiconductor light emitting element 610 with a bump 708 formed of gold or solder on an electrode of semiconductor light emitting element 610, semiconductor light emitting element 610 is simultaneously bonded to substrate 702. By such electrical connection, terminal 707 connected via through hole 706 of substrate 702 to the p and n electrodes of semiconductor light emitting element 610 can provided at a rear surface of substrate 702. After the electrical connection, semiconductor light emitting element 610 is covered with first resin 701 and diced, as has been previously described. Such electrical connection allows a terminal to be provided external to the first resin. This allows the semiconductor light emitting element in the present embodiment to be connected for example to another package after the semiconductor light emitting element has been fabricated. Furthermore in the present embodiment it is preferable to avoid electrical connection of semiconductor light emitting elements 610 to avoid cutting electrical connection in the step of dicing.

Note that if a semiconductor light emitting element other than that capable of flip chip connection, as shown in FIG. 6, is used, it is necessary, in the step of bonding, to connect an electrode of the semiconductor light emitting element to a substrate allowing the electrode to be externally extracted by at least one bonded wire. Furthermore, the step of dicing must carefully be done to avoid cutting the bonded wire.

### Second Embodiment

The present fabrication method and device in another embodiment will be described with reference to FIG. 2.

Initially, at least two semiconductor light emitting elements 201 are bonded to a submount 205. The die-bonding is similar to that in the first embodiment, except that in the present embodiment semiconductor light emitting element 201 is bonded to submount 205. Submount 205 as described herein is a satisfactorily thermally conductive plate having a coefficient of thermal expansion close to that of semiconductor light emitting element 201, and holding semiconductor light emitting element 201 and held by a substrate 202. Substrate 202 holds semiconductor light emitting element 201 via submount 205. In the present invention submount 205 may serve to externally extract an electrode. The number of semiconductor light emitting elements 201 bonded to the submount is not limited to any particular number.

Then, first resin 203 is applied across the entire surface of submount 205 to cover semiconductor light emitting element 201 such that first resin 203 is substantially parallel to a top surface of semiconductor light emitting element 201. The step of molding first resin 203 is similar to that done in the first embodiment.

After first resin 203 is cured, first resin 203 and substrate 202 are penetrated or diced to allow first resin 203 to have thickness D1 on the top surface of semiconductor light emitting element 201 and thickness D2 on a side surface of semiconductor light emitting element 201 such that the ratio of D2/D1 is 0.85 to 1.15. Such dicing provides first resin 203 with a substantially uniform thickness on the top and side surfaces of semiconductor light emitting element 201.

Semiconductor light emitting element 201 of the present invention is preferably the same as the first embodiment, i.e., capable of flip chip connection. Furthermore, semiconductor light emitting element 201 is electrically connected to submount 205 and substrate 202 when semiconductor light emitting element 201 is bonded to submount 205. The electrical connection may be done with any electrical interconnect, although preferably an electrical interconnect is provided for each semiconductor light emitting element 201 singly to avoid cutting off the electrical interconnect in dicing. In other words, preferably, semiconductor light emitting elements 201 are not connected electrically. Submount 205 and substrate 202 may be provided with a through hole to allow electrical connection, as described in the first embodiment. Furthermore, wire-bonding may be employed to electrically connect semiconductor light emitting element 201 to submount 205, and submount 205 may be bonded to substrate 202 having a through hole. Note that in any case, the electrical interconnect must have a terminal provided external to first resin 203.

### Third Embodiment

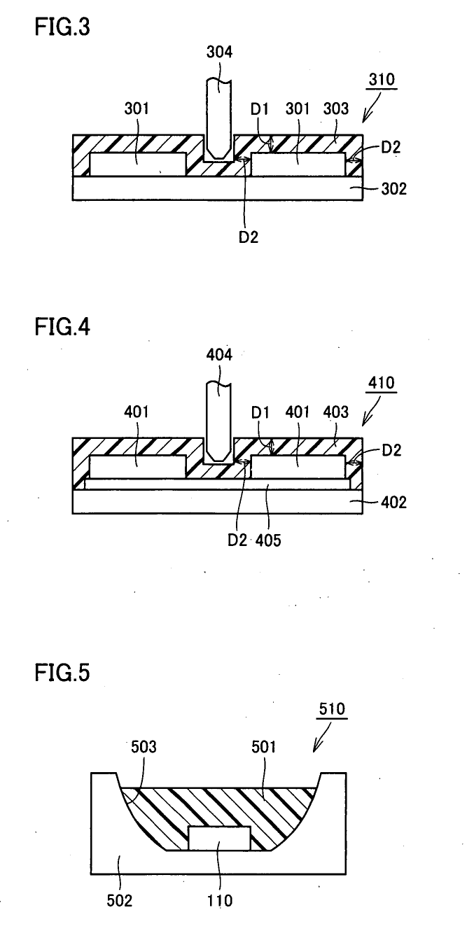

A process similar to that described in the first embodiment is performed up to FIG. 1B. Thereafter, as shown in FIG. 3, after first resin 303 is cured, first resin 303 is diced to a depth allowing first resin 303 to be left by a small amount to have thickness D1 on a top surface of a semiconductor light emitting element 301 and thickness D2 on a side surface of semiconductor light emitting element 301 such that the ratio of D2/D1 is 0.85 to 1.15: In doing so, a dicer 304 dices the first resin at a depth such that it does not contact a substrate 302. Dicing as described in the present embodiment can prevent a semiconductor light emitting device 310 from having substrate 302 having a damaged surface and/or interior. Accordingly when semiconductor light emitting element 301 is bonded to substrate 302 semiconductor light emitting element 301 may simultaneously be interconnected on substrate 302 to provide an interconnect configuring an electrical connection circuit. Furthermore, substrate 302 may be implemented by a large number of substrates having a through hole that are stacked together to internally provide an interconnect. Such interconnect allows semiconductor light emitting elements 301 to be electrically connected together. Semiconductor light emitting element 301 is preferably that capable of flip chip connection, as shown in FIG. 6, as aforementioned. Semiconductor light emitting elements 301 electrically connected together can contribute to saving a space in the semiconductor light emitting device.

Note that in the present embodiment thickness D2 of first resin 303 on the side surface of semiconductor light emitting element 301 refers to a thickness between a section cut or diced by dicer 304 and the side surface of semiconductor light emitting element 301, as shown in FIG. 3. Such dicing provides first resin 303 with a substantially uniform thickness on the top and side surfaces of semiconductor light emitting element 301.

### Fourth Embodiment

A process similar to that described in the second embodiment is performed up to the dicing. Then, as shown in FIG. 4, after first resin 403 is cured, first resin 403 is diced to have thickness D1 on a top surface of a semiconductor light emitting element 401 and thickness D2 on a side surface of semiconductor light emitting element 401 such that the ratio of D2/D1 is 0.85 to 1.15. In doing so, first resin 403 on a submount 405 having semiconductor light emitting element 401 bonded thereto is diced to a depth allowing first resin 403 to be left by a small amount. In doing so, a dicer 404 dices the first resin at a depth such that it does not contact submount 405.

For semiconductor light emitting device 410 when semiconductor light emitting element 401 is bonded to submount 405 semiconductor light emitting element 401 may simultaneously be interconnected on substrate 402 or submount 405 to provide an interconnect configuring an electrical connection circuit. For example, submount 405 with semiconductor light emitting element 401 bonded thereto can be held on substrate 402 formed of an aluminum plate, an insulation layer deposited on the plate, and a copper foil deposited on the layer and forming a circuit pattern. Furthermore, substrate 402 may be implemented by a large number of substrates of thin film having a through hole that are stacked together to internally provide an interconnect.

Such interconnect as described above electrically connects semiconductor light emitting elements 401 together. Semiconductor light emitting element 401 is preferably that capable of flip chip connection, as shown in FIG. 6, as aforementioned. Semiconductor light emitting elements 401 electrically connected together can contribute to saving a space in the semiconductor light emitting device.

Note that in the present embodiment thickness D2 of first resin 403 on the side surface of semiconductor light emitting element 401 refers to a thickness between a section cut or diced by dicer 404 and the side surface of semiconductor light emitting element 401, as shown in FIG. 4. Such dicing provides first resin 403 with a substantially uniform thickness on the top and side surfaces of semiconductor light emitting element 401.

### Fifth Embodiment

Hereinafter, any product that has a semiconductor light emitting element packaged and has a terminal electrically connected to the semiconductor light emitting element will be referred to as a semiconductor light emitting device. Accordingly, a device having such semiconductor light emitting device packaged will also be referred to as a semiconductor light emitting device.

With reference to FIG. 5, an embodiment of the present invention will be described.

Semiconductor light emitting device 110 described in the first embodiment is attached to a package 502, which is a resin mold product having a reflector 503, and surrounded by second resin 501. Package 502 can for example be a ceramic package. Initially semiconductor light emitting device 110 is bonded to package 502 with gold, solder or the like, and simultaneously a terminal provided external to semiconductor light emitting device 110 is electrically connected to that of package 502.

Second resin 501 covering semiconductor light emitting device 110 can protect a diced surface of the first resin and prevent light from scattering at an interface. Accordingly, preferably, the first resin has a larger index of refraction than second resin 501 and second resin 501 is a highly transparent resin.

Furthermore, preferably, the first resin being and having been cured has a smaller modulus of elasticity than second resin 501 being and having been cured, and second resin 501 is smaller in moisture absorptivity than the first resin. The semiconductor light emitting device is covered with second resin 501 in order to prevent light from scattering, as has been described, and in addition protect the semiconductor light emitting element. Accordingly, preferably, second resin 501 is epoxy resin, which is thermosetting resin.

Furthermore a semiconductor light emitting device 510 that includes reflector 503 surrounding the semiconductor light emitting element to reflect light emitted from the semiconductor light emitting element allows the light emitted from the semiconductor light emitting element to be emitted in a particular direction to obtain high luminous intensity.

Note that semiconductor light emitting devices 210, 310, 410 of the second to fourth embodiments can also be used to fabricate a semiconductor light emitting device similar to that of the present embodiment.

### Sixth Embodiment

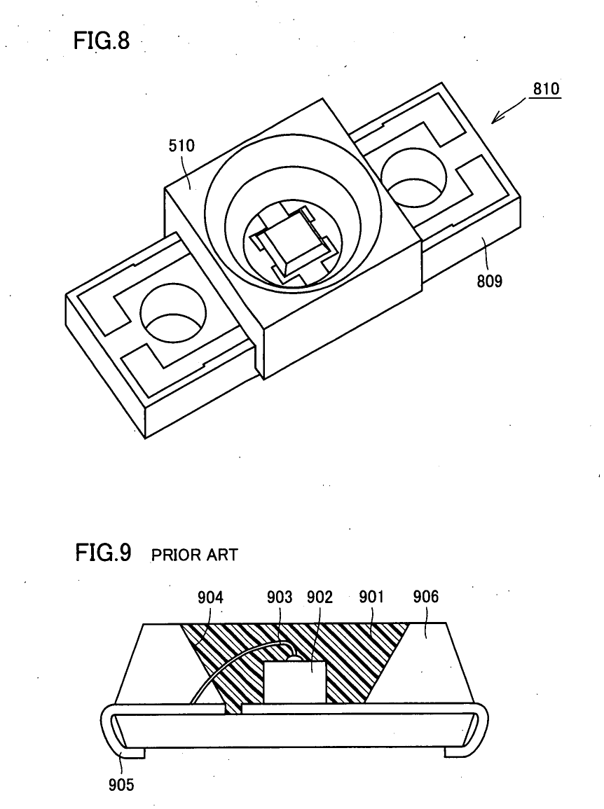

With reference to FIG. 8 an embodiment of the present invention will be described.

Semiconductor light emitting device 510 fabricated in the fifth embodiment is bonded to a metal core substrate 809 and thus mounted to provide a semiconductor light emitting device 810. Metal core substrate 809 as referred to herein is a substrate capable of diffusing heat generated for example by a component mounted. In the first embodiment a substrate and a semiconductor light emitting element are flip-chip-connected, and a path provided through a bump to diffuse heat is inferior to that provided when a substrate of a semiconductor light emitting element is entirely bonded. Accordingly a device is required to approach heat diffusion. Mounting on a substrate such as metal core substrate 809 allows generated heat to be efficiently diffused, and a semiconductor light emitting element to be increased in longevity.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor light emitting device fabricated by a process; comprising the steps of
bonding at least two semiconductor light emitting elements to one of a substrate and a submount with a predetermined interval;
molding a first resin across an entire surface of said one of said substrate and said submount substantially parallel to a top surface of said semiconductor light emitting element to cover said semiconductor light emitting element; and
after said first resin is cured, dicing and thus penetrating said first resin and said substrate to provide said first resin with a thickness D1 and a thickness D2 on said top surface and a side surface, respectively, of said semiconductor light emitting element such that a ratio of D2/D1 is 0.85 to 1.15.

2. The semiconductor light emitting device according to claim 1, wherein said first resin contains a fluorescent substance mixed therein.

3. The semiconductor light emitting device according to claim 1, wherein after the step of dicing, a surface of said first resin covering said semiconductor light emitting element is covered with a second resin.

4. The semiconductor light emitting device according to claim 3, wherein said second resin is epoxy resin.

5. The semiconductor light emitting device according to claim 3, wherein said first resin having been cured has a smaller modulus of elasticity than said second resin having been cured.

6. The semiconductor light emitting device according to claim 3, wherein said second resin is smaller in moisture absorptivity than said first resin.

7. The semiconductor light emitting device according to claim 3, wherein said first resin has a larger index of refraction than said second resin.

8. The semiconductor light emitting device according to claim 3, mounted on a package having a refractor such that the semiconductor light emitting device of claim 1 is surrounded by said reflector.

9. The semiconductor light emitting device according to claim 1, wherein said first resin covering said semiconductor light emitting element has a thickness of 50 μm to 500 μm.

10. The semiconductor light emitting device according to claim 1, wherein said first resin includes silicone resin as a source material.

11. The semiconductor light emitting device according to claim 1, wherein said semiconductor light emitting element has a bottom surface having a p type electrode and an n type electrode.

12. The semiconductor light emitting device according to claim 11, wherein said semiconductor light emitting element is bonded with one of gold and solder to a ceramic substrate electrically conducting via a through hole.

13. The semiconductor light emitting device according to claim 11, wherein said semiconductor light emitting element is bonded with one of gold and solder to a silicon carbide substrate electrically conducting via a through hole.

14. A semiconductor light emitting device fabricated by a process; comprising the steps of
bonding at least two semiconductor light emitting elements to one of a substrate and a submount with a predetermined interval;
molding a first resin across an entire surface of said one of said substrate and said submount substantially parallel to a top surface of said semiconductor light emitting element to cover said semiconductor light emitting element; and
after said first resin is cured, dicing said first resin at least partially to provide said first resin with a thickness D1 and a thickness D2 on said top surface and a side surface, respectively, of said semiconductor light emitting element such that a ratio of D2/D1 is 0.85 to 1.15.

15. The semiconductor light emitting device according to claim 14, wherein said first resin contains a fluorescent substance mixed therein.

16. The semiconductor light emitting device according to claim 14, wherein after the step of dicing, a surface of said first resin covering said semiconductor light emitting element is covered with a second resin.

17. The semiconductor light emitting device according to claim 16, wherein said second resin is epoxy resin.

18. The semiconductor light emitting device according to claim 16, wherein said first resin having been cured has a smaller modulus of elasticity than said second resin having been cured.

19. The semiconductor light emitting device according to claim 16, wherein said second resin is smaller in moisture absorptivity than said first resin.

20. The semiconductor light emitting device according to claim 16, wherein said first resin has a larger index of refraction than said second resin.

21. The semiconductor light emitting device according to claim 16, mounted on a package having a refractor such that the semiconductor light emitting device of claim 14 is surrounded by said reflector.

22. The semiconductor light emitting device according to claim 14, wherein said first resin covering said semiconductor light emitting element has a thickness of 50 μm to 500 μm.

23. The semiconductor light emitting device according to claim 14, wherein said first resin includes silicone resin as a source material.

24. The semiconductor light emitting device according to claim 14, wherein said semiconductor light emitting element has a bottom surface having a p type electrode and an n type electrode.

25. The semiconductor light emitting device according to claim 24, wherein said semiconductor light emitting element is bonded with one of gold and solder to a ceramic substrate electrically conducting via a through hole.

26. The semiconductor light emitting device according to claim 24, wherein said semiconductor light emitting element is bonded with one of gold and solder to a silicon carbide substrate electrically conducting via a through hole.

27. The semiconductor light emitting device according to claim 14, wherein in the step of bonding, said substrate is an aluminum substrate formed of an aluminum plate, an insulation layer overlying said aluminum plate, and a copper foil overlying said insulation layer and forming a circuit pattern.

28. A method of fabricating a semiconductor light emitting device, comprising the steps of:
bonding at least two semiconductor light emitting elements to one of a substrate and a submount with a predetermined interval;
molding a first resin across an entire surface of said one of said substrate and said submount substantially parallel to a top surface of said semiconductor light emitting element to cover said semiconductor light emitting element; and
after said first resin is cured, dicing and thus penetrating said first resin and said substrate to provide said first resin with a thickness D1 and a thickness D2 on said top surface and a side surface, respectively, of said semiconductor light emitting element such that a ratio of D2/D1 is 0.85 to 1.15.

29. A method of fabricating a semiconductor light emitting device, comprising the steps of:
bonding at least two semiconductor light emitting elements to one of a substrate and a submount with a predetermined interval;
molding a first resin across an entire surface of said one of said substrate and said submount substantially parallel to a top surface of said semiconductor light emitting element to cover said semiconductor light emitting element; and
after said first resin is cured, dicing said first resin at least partially to provide said first resin with a thickness D1 and a thickness D2 on said top surface and a side surface, respectively, of said semiconductor light emitting element such that a ratio of D2/D1 is 0.85 to 1.15.
